(19) United States
(12) Patent Application Publication
(10) Pub. No.: US 2024/0394668 A1
(43) Pub. Date: Nov. 28, 2024

(54) SUBSTRATE PROCESSING APPARATUS, MAINTENANCE METHOD, AND RECORDING MEDIUM

(71) Applicant: Tokyo Electron Limited, Tokyo (JP)

(72) Inventors: Tomonori OKUMURA, Kumamoto (JP); Manabu YAMANAKA, Kumamoto (JP)

(21) Appl. No.: 18/672,248

(22) Filed: May 23, 2024

(30) Foreign Application Priority Data
May 24, 2023 (JP) 2023-085119

(51) Int. Cl. G06Q 10/20; G06Q 50/26

(52) U.S. Cl. CPC G06Q 10/20; G06Q 50/265

(57) ABSTRACT

A substrate processing apparatus that processes a substrate includes a housing having an accommodation space that accommodates a device used to process the substrate, a switch that switches the accommodation space between an open state and a closed state, a detection unit provided around the housing to detect protective gear worn by an operator, and a control unit that controls an operation of the switch. The control unit determines whether the worn protective gear detected by the detector is pre-registered protective gear corresponding to the housing, and when determined that the worn protective gear is the corresponding protective gear, the control unit switches the accommodation space from the closed state to the open state.

### CROSS-REFERENCE TO RELATED APPLICATIONS

This application is based on and claims priority from Japanese Patent Application No. 2023-085119, filed on May 24, 2023, with the Japan Patent Office, the disclosure of which is incorporated herein in its entirety by reference.

### TECHNICAL FIELD

The present disclosure relates to a substrate processing apparatus, a maintenance method, and a storage medium.

### BACKGROUND

Japanese Patent Laid-Open Publication No. 2021-077759 discloses a monitoring system for a sealing device that seals a substrate processing apparatus by a housing and fills a sealed space with a predetermined gas atmosphere. The monitoring system includes a laser sensor that defines an area that humans can access as a detection area in the space between the housing and the substrate processing apparatus, and a control device that outputs a control signal to the substrate processing apparatus or the sealing device based on the detection result of the laser sensor, or outputs a notification signal based on the detection result.

### SUMMARY

An aspect of the present disclosure is a substrate processing apparatus including a housing having an accommodation space that accommodates an apparatus used to process the substrate, a switch that switches the accommodation space between an open state and a closed state, a detection unit that is provided around the housing and detects a protective gear worn by an operator, and a control unit that controls an operation of the switch, in which the controller determines whether the worn protective gear detected by the detector is pre-registered protective gear corresponding to the housing, and when it is determined that the worn protective gear is the corresponding protective gear, the control unit e switches the accommodation space from the closed state to the open state.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is an explanatory diagram schematically illustrating an internal configuration of a coating/development processing apparatus as a substrate processing apparatus according to the present embodiment.

FIG. 2 is an explanatory diagram schematically illustrating an internal configuration of the front side of the coating/development processing apparatus of FIG. 1.

FIG. 3 is an explanatory diagram schematically illustrating an internal configuration of the back side of the coating/development processing apparatus of FIG. 1.

FIG. 4 is a longitudinal cross-sectional view schematically illustrating a configuration of a heat treatment unit.

FIG. 5 is an explanatory diagram schematically illustrating a configuration of a door with a locking mechanism.

FIG. 6 is an explanatory diagram illustrating a heat-resistant glove with an RFID tag.

FIG. 7 is a diagram illustrating an example of a maintenance workflow for the heat treatment unit by an operator.

FIG. 8 is an explanatory diagram illustrating the unlocking of the door during maintenance work.

FIG. 9 is a longitudinal cross-sectional view schematically illustrating a configuration of a resist coating unit.

FIG. 10 is a longitudinal cross-sectional view schematically illustrating a configuration of an ultraviolet irradiation unit.

FIG. 11 is a longitudinal cross-sectional view schematically illustrating a configuration of a gas processing unit.

FIG. 12 is an explanatory diagram schematically illustrating an internal configuration of a cleaning system as a substrate processing apparatus.

FIG. 13 is a longitudinal cross-sectional view schematically illustrating a configuration of a cleaning unit.

FIG. 14 is an explanatory diagram illustrating an accommodation container of a liquid reservoir.

FIG. 15 is an explanatory diagram illustrating an electrical component accommodating section, a maintenance operator identifier, a display, and an emitter.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

In the manufacturing process of semiconductor devices and others, a predetermined processing is performed to form a resist pattern on a semiconductor wafer (hereinafter referred to as a “wafer”). Examples of the predetermined processing includes a resist coating processing to supply a resist onto a wafer to form a resist film, an exposure processing to expose the resist film, a wafer heating processing such as PAB processing or PEB processing, a wafer cleaning processing, etc.

In each of processing apparatuses for performing the aforementioned processings, maintenance work by operators is performed regularly or in emergency situations. Meanwhile, it is necessary to consider the safety of the operators who perform the maintenance work in each processing apparatus because, for example, the inside of a processing container is at a high temperature, or special processing liquids or gases are used to process wafers W.

For example, in a heat treatment apparatus where the inside of a processing container is at a high temperature, a safety measure is conceivable, which involves attaching a door with an electronic locking device to the processing container, where the electronic locking device remains locked until the high temperature inside the processing container decreases to a predetermined temperature (e.g., below 50° C.). However, with such a measure, maintenance work cannot be performed until the temperature inside the processing container has sufficiently decreased.

Therefore, for example, it is conceivable that an operator wears protective gear such as heat-resistant gloves to begin maintenance work before the temperature inside the processing container decreases. However, it is necessary to ensure safety so that maintenance work is not performed without the operator wearing appropriate protective gear.

Accordingly, the technology according to the present disclosure is intended to improve the safety of operators during maintenance work on a substrate processing apparatus.

Hereinafter, a substrate processing apparatus according to the present embodiment will be described with reference to the drawings. In this specification and drawings, the same reference numerals will be given to elements having substantially the same functional configuration, and redundant descriptions thereof will be omitted.

### <Coating/Development Processing Apparatus>

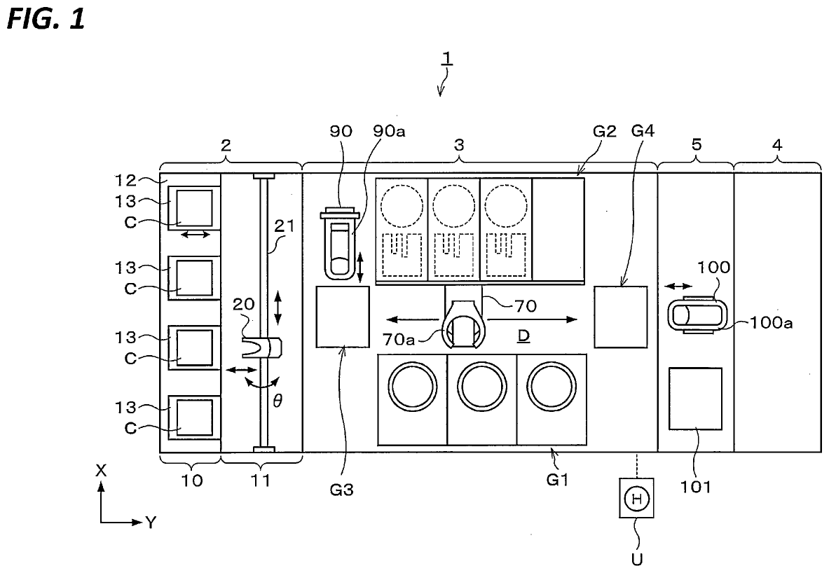

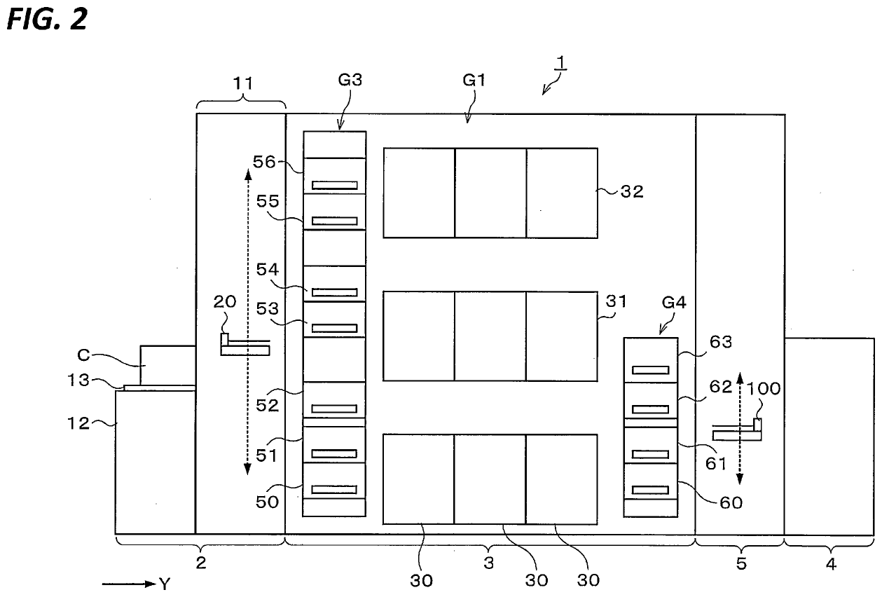

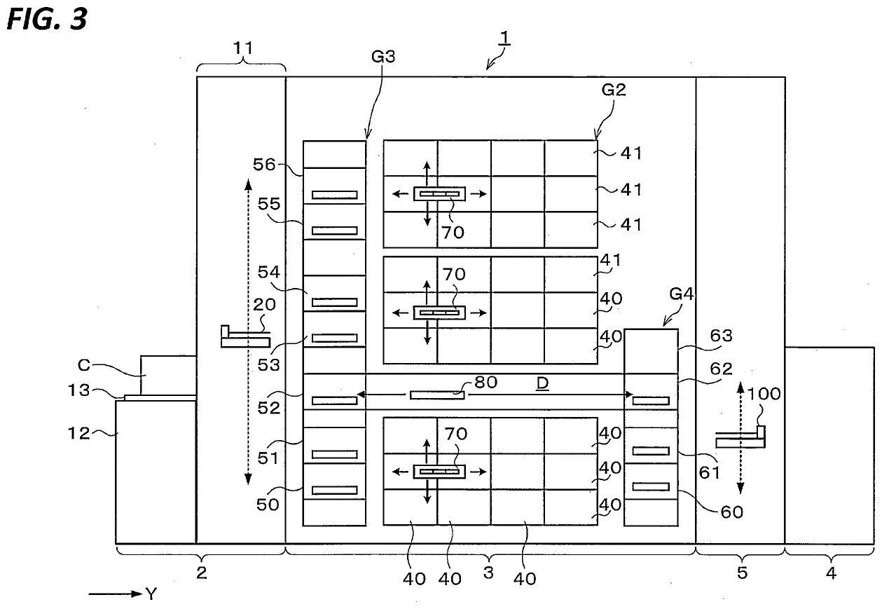

FIG. 1 is an explanatory diagram schematically illustrating an internal configuration of a coating/development processing apparatus as a substrate processing apparatus according to the present embodiment. FIGS. 2 and 3 are respectively explanatory diagrams schematically illustrating an internal configuration of the front side and back side of the coating/development processing apparatus 1.

As illustrated in FIGS. 1 to 3, the coating/development processing apparatus 1 includes a cassette station 2 where cassettes C, which are containers each capable of accommodating a plurality of wafers as substrates, are loaded and unloaded, and a processing station 3 having a plurality of various processing units that perform predetermined processings such as a resist coating processing. Also, the coating/development processing apparatus 1 is configured such that the cassette station 2 and the processing station 3 are integrally connected to an interface station 5 that delivers the wafers between the processing station 3 and an exposure device 4 adjacent thereto.

The cassette station 2 is divided, for example, into a cassette loading/unloading section 10 and a wafer transfer section 11. For example, the cassette loading/unloading section 10 is provided at the end of the negative Y-direction side of the coating/development processing apparatus 1. The cassette loading/unloading section 10 is provided with a cassette stage 12. A plurality of, for example, four placement plates 13 are provided on the cassette stage 12. The placement plates 13 are arranged in a line in the horizontal X-direction (the vertical direction in FIG. 1). The cassettes C may be placed on these placement plates 13 when loading or unloading the cassettes C to or from the outside of the coating/development processing apparatus 1.

The wafer transfer section 11 is provided with a transfer unit 20 for transferring the wafers. The transfer unit 20 is configured to freely move along a transfer path 21 extending in the X-direction. The transfer unit 20 is freely movable in the vertical direction and around a vertical axis (θ-direction), enabling the transfer of wafers between the cassette C on each placement plate 13 and a delivery device of a third block G3 of the processing station 3 to be described later.

The processing station 3 is provided with a plurality of, e.g. four, first to fourth blocks G1, G2, G3 and G4 having various units. For example, the first block G1 is provided on the front side (negative X-direction side in FIG. 1) of the processing station 3, and the second block G2 is provided on the back side (positive X-direction side in FIG. 1) of the processing station 3. Further, the third block G3 is provided on the cassette station 2 side (negative Y-direction side in FIG. 1) of the processing station 3, and the fourth block G4 is provided on the interface station 5 side (positive Y-direction side in FIG. 1) of the processing station 3.

In the first block G1, as illustrated in FIG. 2, a plurality of liquid processing units as liquid processing apparatuses such as a development processing unit 30 and a resist coating unit 31 are arranged in this order from bottom. A gas processing unit 32 as a gas processing apparatus is arranged above the resist coating unit 31. Further, the development processing unit 30, the resist coating unit 31, and the gas processing unit 32 are each arranged in three rows in the horizontal direction. The number and arrangement of these development processing unit 30, resist coating unit 31, and gas processing unit 32 may be arbitrarily selected.

The development processing unit 30 performs a development processing on the wafer. Specifically, the development processing unit 30 performs a development processing on a resist film of the wafer that has undergone a PEB processing. The resist coating unit 31 applies a resist to the wafer to form the resist film.

The development processing unit 30 and the resist coating unit 31 apply a predetermined processing liquid onto the wafer by, for example, a spin coating method. In the spin coating method, for example, the processing liquid is discharged onto the wafer from a discharge nozzle while the wafer is rotated, thus spreading the processing liquid over a surface of the wafer.

The gas processing unit 32 performs an acidic atmosphere processing, for example, by locally spraying a processing gas containing an acidic gas onto the wafer.

In the second block G2, as illustrated in FIG. 3, heat treatment units 40, which serve as heat treatment apparatuses to perform a heat treatment such as heating or cooling of the wafer, are arranged in the vertical and horizontal directions. Above a group of these heat treatment units 40, ultraviolet irradiation units 41, which serve as ultraviolet irradiation devices to irradiate the wafers with ultraviolet rays, are arranged in the vertical and horizontal directions. Here, the number and arrangement of these heat treatment units 40 and ultraviolet irradiation units 41 may be selected arbitrarily.

The heat treatment units 40 perform a PAB processing, PEB processing, post-baking processing to heat the wafer after a development processing, and other processings. The ultraviolet irradiation units 41 perform a modification processing for a film formed on the wafer, and other processings.

The third block G3 is provided with a plurality of delivery units 50, 51, 52, 53, 54, 55, and 56 arranged sequentially from bottom. Further, the fourth block G4 is provided with a plurality of delivery units 60, 61, 62, and 63 arranged sequentially from bottom.

As illustrated in FIG. 1, an area surrounded by the first block G1 to the fourth block G4 forms a wafer transfer area D. In the wafer transfer area D, for example, a transfer unit 70, which serves as a substrate transfer unit to transfer the wafers, is arranged.

The transfer unit 70 has a transfer arm 70a that is freely movable, for example, in the Y-direction, the θ-direction, and the vertical direction. The transfer unit 70 may move the transfer arm 70a holding the wafer within the wafer transfer area D, and may transfer the wafer to a predetermined unit within the surrounding first block G1, second block G2, third block G3, and fourth block G4. As illustrated in FIG. 3, several transfer units 70 may be arranged vertically, for example, and may transfer the wafers to, for example, predetermined units at similar heights in the respective blocks G1 to G4.

Further, the wafer transport area D is provided with a shuttle transfer unit 80 to transfer the wafer linearly between the third block G3 and the fourth block G4.

The shuttle transfer unit 80 may move the supported wafer linearly in the Y-direction, and may transfer the wafer between the delivery unit 52 of the third block G3 and the delivery unit 62 of the fourth block G4, which are at similar heights.

As illustrated in FIG. 1, a transfer unit 90 is provided on the positive X-direction side of the third block G3. The transfer unit 90 has a transfer arm 90a that is freely movable, for example, in the X-direction, the θ-direction, and the vertical direction. The transfer unit 90 may move the transfer arm 90a holding the wafer vertically, thus transferring the wafer to each of the delivery units 50 to 56 within the third block G3.

The interface station 5 is provided with a transfer unit 100 and a delivery unit 101. The transfer unit 100 has a transfer arm 100a that is freely movable, for example, in the θ-direction and the vertical direction. The transfer unit 100 may hold the wafer on the transfer arm 100a, and may transfer the wafer between each of the delivery units 60 to 63 within the fourth block G4 and the exposure device 4.

The above coating/development processing apparatus 1 is provided with a controller U as illustrated in FIG. 1. The controller U is a computer equipped with, for example, a processor such as CPU, a memory, etc., and has a program storage (not illustrated). The program storage stores programs that control the operations of various processing units and various transfer units described above, or the operation of an electronic locking device serving as a switch to be described later. The above programs were recorded on a computer-readable storage medium H, and may be installed from the storage medium H to the controller U. The storage medium M may be either transitory or non-transitory. Some or all of the programs may be realized with dedicated hardware (circuit board).

### (Heat Treatment Unit)

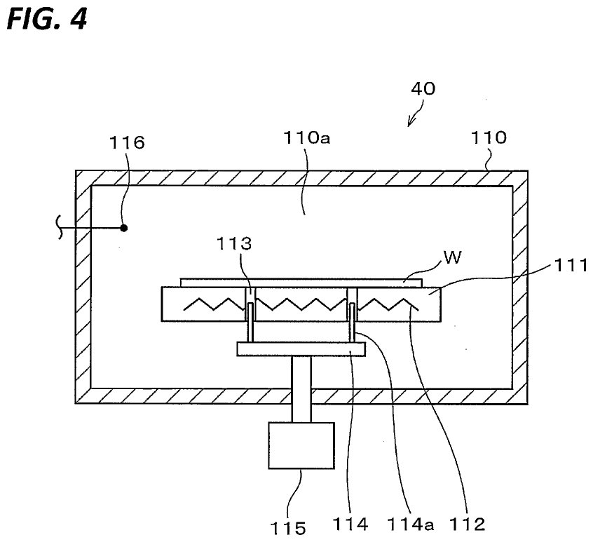

Here, a schematic configuration of the heat treatment unit 40 will be described. FIG. 4 is a longitudinal cross-sectional view schematically illustrating a configuration of the heat treatment unit 40. The heat treatment unit 40 includes a processing container 110 as a housing, and the processing container 110 has an accommodation space 110a that accommodates a device for heating the wafer W.

A loading/unloading port (not illustrated) for the wafer W is formed on the side of the processing container 110, and a stage 111 is provided as a substrate holder to place the wafer W within the processing container 110. A heater 112, which serves as a heating part for the wafer W, is embedded in the stage 111. The stage 111 has through-holes 113 formed at several locations, and lifting pins 114a, which move up and down in these through-holes 113, are fixed to a lifting pin support 114. The lifting pin support 114 is moved up and down by a lifting mechanism 115.

The processing container 110 is provided with a temperature sensor 116 to measure the temperature inside the accommodating space 110a. Information on the temperature measured by the temperature sensor 116 is output to the controller U illustrated in FIG. 1.

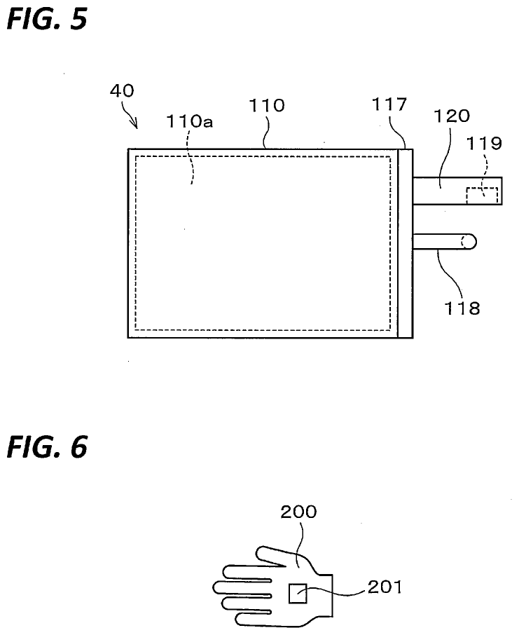

As illustrated in FIG. 5, an opening/closing door 117 with an electronic locking device is attached to the side of the processing container 110. The door 117 is used during maintenance work on the heat treatment unit 40. A handle 118, which has a U-shaped shape when viewed from the right, is attached to the door 117, and the operator opens or closes the door 117 by grasping the handle 118.

The electronic locking device (not illustrated) attached to the door 117 may be switched between the operational state and the release state based on a signal from the controller U. When the operator attempts to perform maintenance work on the heat treatment unit 40, the electronic locking device is in the operational state with the inside of the processing container 110 at a high temperature (e.g., 200° C.). The electronic locking device is released when the temperature inside the processing container 110 decreases below a predetermined temperature (e.g., 50° C.).

In the present embodiment, the state where the electronic locking device (not illustrated) is released is referred to as the open state of the accommodation space 110a, and the state where the electronic locking device is operational is referred to as the closed state of the accommodation space 110a. The door 117 with the electronic locking device is an example of a switch that switches the accommodation space 110a between the open state and the closed state. Further, a locking mechanism for the door 117 is not limited to the electronic locking device, and a mechanism capable of switching between locking and unlocking based on a signal from the controller U may also be applied.

An RFID reader 119, which serves as a detector to read information from a radio frequency identification (RFID) tag, is provided above the handle 118 of the door 117. The RFID reader 119 is attached to the tip end of a support 120 extending in the same direction as the direction in which the handle 118 protrudes from the door 117. The RFID reader 119 is oriented such that the reading range thereof faces downward, and information from the RFID tag read by the RFID reader 119 is transmitted to the controller U illustrated in FIG. 1.

In the present embodiment, when performing maintenance work on the heat treatment unit 40, the operator wears a heat-resistant glove 200 as protective gear, as illustrated in FIG. 6. The heat-resistant glove 200 is made of a heat-resistant material that may protect the operator from heat inside the processing container 110, which is at a high temperature immediately after the heat treatment unit 40 stops operating. An RFID tag 201 is attached to the back of the heat-resistant glove 200.

Meanwhile, the controller U illustrated in FIG. 1 pre-stores the ID number of the RFID tag 201 of the heat-resistant glove 200 suitable for maintenance work on the heat treatment unit 40. In other words, information on the heat-resistant glove 200 for the heat treatment unit 40 is pre-registered in the controller U. In this specification, such pre-registered protective gear is designated to correspond to maintenance work on a maintenance target and is referred to as “corresponding protective gear.”

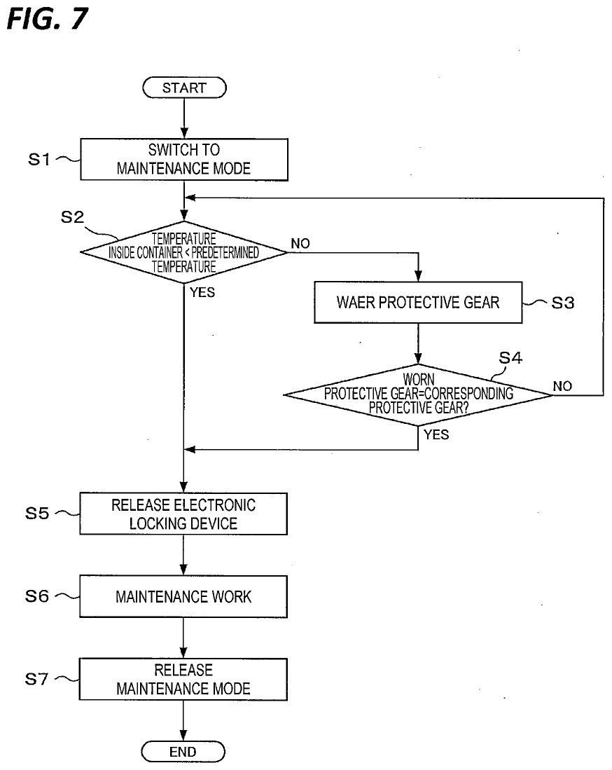

As above, a schematic configuration of the heat treatment unit 40 according to the present embodiment has been described. Next, a maintenance method for the heat treatment unit 40 of the coating/development processing apparatus 1 will be described. FIG. 7 is a diagram illustrating an example of a maintenance workflow for the heat treatment unit 40 by the operator.

### (Step S1)

First, the operator operates an operation panel (not illustrated) of the coating/development processing apparatus 1 to switch the operation mode of the apparatus to the maintenance mode. The inside of the processing container 110 of the heat treatment unit 40 is at a high temperature (e.g., 200° C.) immediately after transitioning to the maintenance mode, and the electronic locking device (not illustrated) of the door 117 remains in the operational state.

### (Step S2)

Next, the controller U determines whether the temperature inside the processing container 110 is below a predetermined temperature. The predetermined temperature referred to here is a sufficiently low temperature (e.g., 50° C.) at which maintenance work inside the processing container 110 is possible even without the operator wearing the heat-resistant glove.

When the temperature inside the processing container 110 was below the predetermined temperature in step S2, the method proceeds to step S5. Meanwhile, when the temperature inside the processing container 110 was equal to or greater than the predetermined temperature in step S2, the method proceeds to step S3.

### (Step S3)

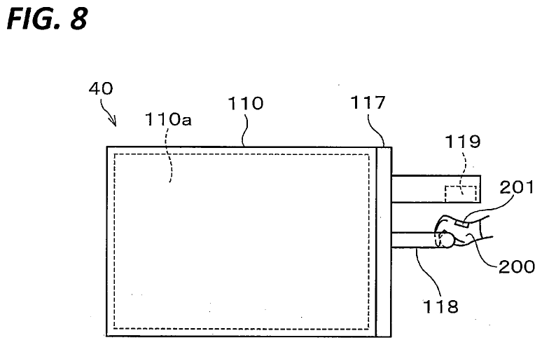

When initiating maintenance work while the temperature inside the processing container 110 has not sufficiently decreased, the operator wears the heat-resistant glove 200 and grasps the handle 118 of the door 117, as illustrated in FIG. 8. At this time, the RFID tag 201 attached to the back of the heat-resistant glove 200, which the operator is wearing while grasping the handle 118, enters the reading range of the RFID reader 119, and the ID number of the RFID tag 201 is read. Here, the read ID number of the RFID tag 201 is transmitted to the controller U illustrated in FIG. 1.

### (Step S4)

Next, the controller U determines whether the ID number of the RFID tag 201 read by the RFID reader 119 matches the ID number pre-stored in the controller U. In other words, the controller U determines whether the heat-resistant glove 200 as protective gear worn by the operator is registered as corresponding protective gear for the heat treatment unit 40.

When the heat-resistant glove 200 worn by the operator is not registered as the corresponding protective gear in step S4, the method returns to step S2. Meanwhile, when the heat-resistant glove 200 worn by the operator is registered as the corresponding protective gear in step S4, the method returns to step S5.

### (Step S5)

When the temperature inside the processing container 110 was below the predetermined temperature in step S2, the electronic locking device is released. Further, even when the temperature inside the processing container 110 is equal to or greater than the predetermined temperature, the electronic lock device is also released when the heat-resistant glove 200 worn by the operator is registered as the corresponding protective gear.

As a result of the electronic locking device being released, the accommodation space 110a within the processing container 110 is switched from the closed state to the open state, allowing the operator to open the door 117.

### (Step S6)

Afterwards, the operator opens the door 117 to perform maintenance work on the heat treatment unit 40.

### (Step S7)

After predetermined maintenance work by the operator is completed, the door 117 is closed, and the operation panel of the coating/development processing apparatus 1 is operated to release the maintenance mode.

As described above, according to the maintenance method for the heat treatment unit 40 of the present embodiment, the door 117 will not be unlocked when the heat-resistant glove 200 as protective gear worn by the operator is not registered as the corresponding protective gear for the heat treatment unit 40. For example, when the operator incorrectly wears a heat-resistant glove with a lower heat resistance temperature than the heat-resistant glove 200 for the heat treatment unit 40, the door 117 will not be unlocked because the ID number of the incorrectly worn heat-resistant glove is not registered in the controller U. In other words, the electronic locking device is released only when predetermined protective gear is worn, which enhances the safety of operators during maintenance work.

Further, according to the maintenance method for the heat treatment unit 40 of the present embodiment, the time from the stop of operation to the restart of the heat treatment unit 40 may be reduced because maintenance work may be initiated without waiting for the temperature inside the processing container 110 to decrease after the heat treatment unit 40 has stopped operating.

Furthermore, during maintenance work, when the temperature inside the processing container 110 has sufficiently decreased, the electronic locking device is released regardless of whether the heat-resistant glove 200 is worn or not. In other words, when the temperature inside the processing container 110 has sufficiently decreased, the wearing of the heat-resistant glove 200 may be omitted, allowing maintenance work to be initiated promptly.

In the present embodiment, the RFID tag 201 is attached to the back of the heat-resistant glove 200, and the RFID reader 119 is oriented such that the reading range thereof faces downward. However, the attachment site of the RFID tag 201 to the heat-resistant glove 200 and the installation site of the RFID reader 119 are not limited to a positional relationship described in the present embodiment.

For example, it is permissible to attach the RFID reader 119 directly to the door 117 without providing the support 120. In this case, the electronic locking device may be released by presenting the RFID tag 201 of the heat-resistant glove 200 to the RFID reader 119, followed by grasping the handle 118 to open the door 117.

However, as described in the above-described embodiment, it is desirable to orient the RFID reader 119 such that the reading range thereof faces downward above the handle 118. This may simplify the operation until the electronic locking device is released by enabling the RFID tag 201 to be read simultaneously while grasping the handle 118 of the door 117. In addition to this, the downward-facing reading surface of the RFID reader 119 may prevent contamination of the reading surface.

### Other Application Examples

In the above description, the heat-resistant glove 200 was used as protective gear because a maintenance target was the heat treatment unit 40, but protective gear to be used depends on the maintenance target. In the following description, an example of applying protective gear with an RFID tag to another maintenance target having a housing to which a door with an electronic locking device is attached will be described.

### (Resist Coating Unit)

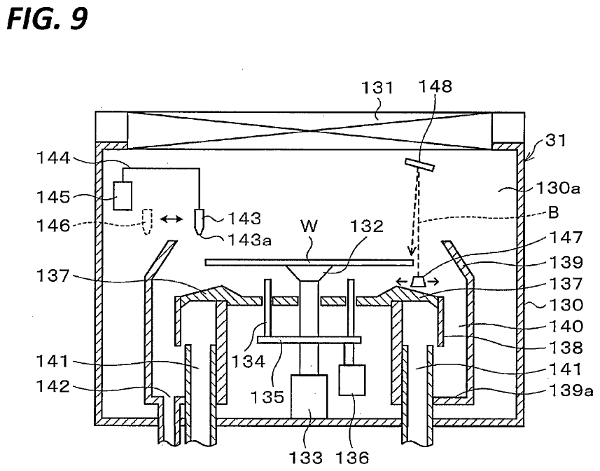

FIG. 9 is a longitudinal cross-sectional view schematically illustrating a configuration of the resist coating unit 31. The resist coating unit 31 is configured as a device that forms a resist film as a coating film on a surface of the wafer W and subsequently removes the unnecessary resist film from the peripheral edge.

The resist coating unit 31 includes a processing container 130 as a housing, and the processing container 130 has an accommodation space 130a that accommodates a device used in a resist coating processing. An air supply 131 is provided at the top within the processing container 130 to downwardly supply clean air as a downward flow from an FFU (not illustrated).

A spin chuck 132 is provided as a substrate holder to hold and rotate the wafer W below the air supply 131 within the processing container 130. The spin chuck 132 is configured to horizontally hold the wafer W, which is a circular substrate with a diameter of, for example, 300 mm, by vacuum suction. The spin chuck 132 is connected to a rotation drive 133 including a motor, etc. The rotation drive 133 rotates the spin chuck 132 around a vertical axis at a rotation speed corresponding to a control signal output from the controller U (FIG. 1).

The transfer of the wafer W to the spin chuck 132 by a transfer device (not illustrated) is accomplished by the vertical movement of three support pins 134 (only two are illustrated in the drawing for convenience) that support the back surface of the wafer W. The support pins 134 are provided on a base 135, and the base 135 is freely movable up and down by the driving of a lifting mechanism 136.

A guide ring 137 with a cross-sectional shape resembling a mountain is provided below the spin chuck 132, and a downwardly extending annular outer peripheral wall 138 is provided on the outer peripheral edge of the guide ring 137. Then, a cup 139 is arranged to surround the spin chuck 132 and the guide ring 137.

The cup 139 has an open upper side, allowing the transfer of the wafer W to the spin chuck 132. A gap 140 configuring a discharge path is formed between an inner peripheral surface of the cup 139 and the outer peripheral wall 138 of the guide ring 137. The cup 139 is provided at a bottom 139a thereof with an exhaust pipe 141 extending upward from the bottom 139a. Further, a drain port 142 is formed at the bottom 139a of the cup 139.

The resist coating unit 31 includes a resist nozzle 143 that supplies a resist liquid onto the wafer W held by the spin chuck 132. The resist nozzle 143 has a discharge port 143a formed on a lower end surface thereof. The resist nozzle 143 is connected to a resist liquid source 145 where which a resist liquid is stored through a resist liquid supply path 144. The resist liquid source 145 includes a pump to pump the resist liquid toward the resist nozzle 143, and the pumped resist liquid is discharged from the discharge port 143a. The supply and stop of the resist liquid is controlled based on a control signal output from the controller U (FIG. 1).

The resist nozzle 143 is configured to be movable in the horizontal and vertical directions, and may move between a standby position 146 provided outside the cup 139 and above the center of the wafer W.

The resist coating unit 31 includes an emitter, i.e., a laser emitter 147. The laser emitter 147 is positioned below an end of the wafer W held by the spin chuck 132 and above the guide ring 137. The laser emitter 147 emits laser light B upward in the vertical direction, as illustrated in FIG. 9. Further, the laser emitter 147 may move in the horizontal direction and in the radial direction of the wafer W held by the spin chuck 132 by a driving member (not illustrated), as indicated by the arrows in FIG. 9.

The laser light B emitted from the laser emitter 147 is directed to a mirror 148 serving as a reflector. The mirror 148 is positioned above the end of the wafer W held by the spin chuck 132.

When performing maintenance work on the resist coating unit 31 described above, protective gear to be used may be, for example, resist-liquid protective goggles to protect the operator's eyes from splashing resist liquid, or chemical-resistant gloves or chemical-resistant aprons made of chemical-resistant materials. Further, laser light is used for the wafer W in the resist coating unit 31. In such a unit for emitting laser light, protective gear to be used may be, for example, laser-light protective goggles to protect the operator's eyes from laser light, or heat-resistant gloves.

By attaching RFID tags to the protective gear and pre-registering the protective gear as corresponding protective gear in the controller U (FIG. 1), similar control to the maintenance method for the heat treatment unit 40 described above may be implemented. In other words, when performing maintenance work, an RFID tag of protective gear worn by the operator may be read, and an electronic locking device of a door attached to the processing container 130 may be released only when the protective gear worn by the operator matches corresponding protective gear.

When multiple corresponding protective gear are registered for one maintenance target, the electronic locking device will be released only when the wearing of all of corresponding protective gear is confirmed. For example, when three types of protective gear, including resist-liquid protective goggles, chemical-resistant gloves, and chemical-resistant aprons, are registered as corresponding protective gear, but the operator is wearing only two protective gear, i.e., resist-liquid protective goggles and chemical-resistant gloves, the controller U will determine that the worn protective gear does not match the corresponding protective gear, and thus, the electronic locking device will not be released.

Further, in the development processing unit 30 illustrated in FIG. 1, a developing liquid is used as a processing liquid. Therefore, in the development processing unit 30, it is desirable to register, for example, developing-liquid protective goggles, chemical-resistant gloves, and chemical-resistant aprons as corresponding protective gear.

### (Ultraviolet Irradiation Unit)

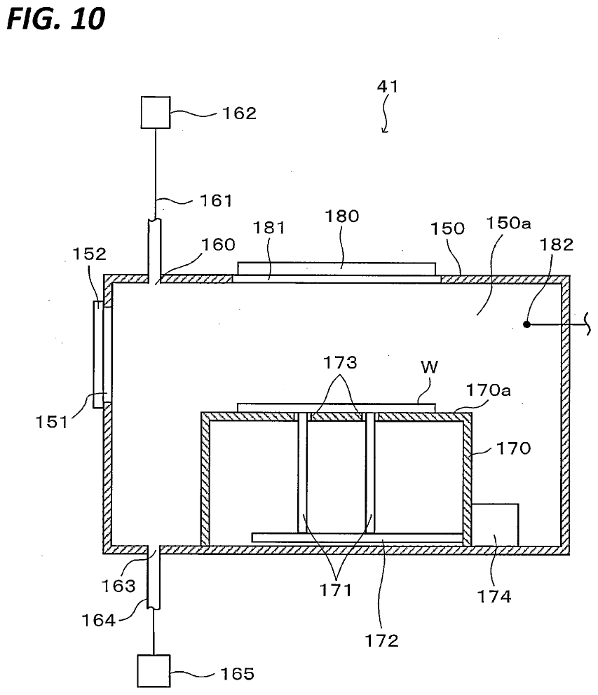

FIG. 10 is a longitudinal cross-sectional view schematically illustrating a configuration of the ultraviolet irradiation unit 41. The ultraviolet irradiation unit 41 includes a processing container 150 as a housing that may be sealed internally, as illustrated in FIG. 10. The processing container 150 has an accommodation space 150a that accommodates a device used to irradiate the wafer W with ultraviolet rays. A loading/unloading port 151 for the wafer W is formed on the side of the processing container 150, and an opening/closing shutter 152 is provided at the loading/unloading port 151.

A gas supply port 160 is formed on an upper surface of the processing container 150 to supply a gas other than oxygen gas, for example, an inert gas such as nitrogen gas, toward the inside of the processing container 150. The gas supply port 160 is connected to a gas supply mechanism 162 through a gas supply pipe 161. The gas supply mechanism 162 includes, for example, a flow adjustment valve (not illustrated) to adjust the gas supply flow rate into the processing container 150. By introducing the gas other than oxygen gas into the processing container 150 using the gas supply mechanism 162, the oxygen concentration inside the processing container 150 may be reduced to 0.1 ppm or less, creating a low-oxygen atmosphere.

An exhaust port 163 is formed on a lower surface of the processing container 150 to exhaust the atmosphere inside the processing container 150, and an exhaust mechanism 165 is connected to the exhaust port 163 through an exhaust pipe 164 to exhaust the atmosphere inside the processing container 150. The exhaust mechanism 165 includes an exhaust pump (not illustrated), etc. By introducing the gas other than oxygen gas from the gas supply port 160 and exhausting the atmosphere from the exhaust port 163, the atmosphere inside the processing container 150 may be quickly replaced with the low-oxygen atmosphere of 0.1 ppm or less.

A cylindrical support 170 is provided inside the processing container 150 to horizontally place the wafer W. Lifting pins 171 for transferring the wafer W are provided inside the support 170 and are supported by a support member 172. The lifting pins 171 are adapted to pass through holes 173 formed in an upper surface 170a of the support 170, and for example, three are provided. A drive mechanism 174 is provided at a base end of the support member 172 to move the support member 172 up and down and thus move the lifting pins 171 up and down. The drive mechanism 174 includes a drive source (not illustrated) such as a motor to generate a drive force for moving the support member 172 up and down.

A light source 180 such as a deuterium lamp or excimer lamp, which irradiates the wafer W on the support 170 with ultraviolet rays with a wavelength of, for example, 172 nm, is provided above the processing container 150. The light source 180 may irradiate the entire surface of the wafer W with ultraviolet rays. A window 181 is provided on a ceiling plate of the processing container 150 to transmit ultraviolet rays from the light source 180.

When performing maintenance work on the ultraviolet irradiation unit 41 described above, protective gear to be used may be, for example, ultraviolet-light protective goggles to protect the operator's eyes from ultraviolet rays (ultraviolet light), or chemical-resistant gloves.

By attaching RFID tags to the protective gear and pre-registering the protective gear as corresponding protective gear in the controller U (FIG. 1), similar control to the maintenance method for the heat treatment unit 40 described above may be implemented. In other words, when performing maintenance work, an RFID tag of protective gear worn by the operator may be read, and an electronic locking device of a door attached to the processing container 150 may be released only when the protective gear worn by the operator matches corresponding protective gear.

By the way, in the ultraviolet irradiation unit 41, the inside of the processing container 150 may become an ozone atmosphere. Therefore, it is desirable to register a gas mask as corresponding protective gear from the viewpoint of further enhancing the safety of operators performing maintenance work.

Further, it is desirable to provide a gas concentration sensor 182 in the ultraviolet irradiation unit 41 to measure the ozone gas concentration within the processing container 150. Information on the gas concentration measured by the gas concentration sensor 182 is output to the controller U illustrated in FIG. 1.

Then, the same control as steps S1 to S7 may be performed by replacing the temperature inside the processing container with the ozone gas concentration within the processing container and replacing a predetermined temperature with a predetermined concentration, for example, in step S2 illustrated in FIG. 7. In other words, when protective gear worn by the operator does not match corresponding protective gear, the electronic locking device may be released when the ozone gas concentration measured by the gas concentration sensor 182 is below a predetermined concentration. The predetermined concentration referred to here is the ozone gas concentration that enables safe breathing for the operator even without wearing a gas mask.

By performing such control, when the ozone gas concentration within the processing container 150 has sufficiently decreased during maintenance work, the electronic locking device may be released regardless of whether the gas mask is worn. In other words, when the ozone gas concentration within the processing container 150 has sufficiently decreased, the wearing of the gas mask may be omitted, allowing maintenance work to be initiated promptly.

At this time, both a device emitting ultraviolet rays (ultraviolet light) and the aforementioned device emitting laser light are examples of a light irradiation apparatus.

### (Gas Processing Unit)

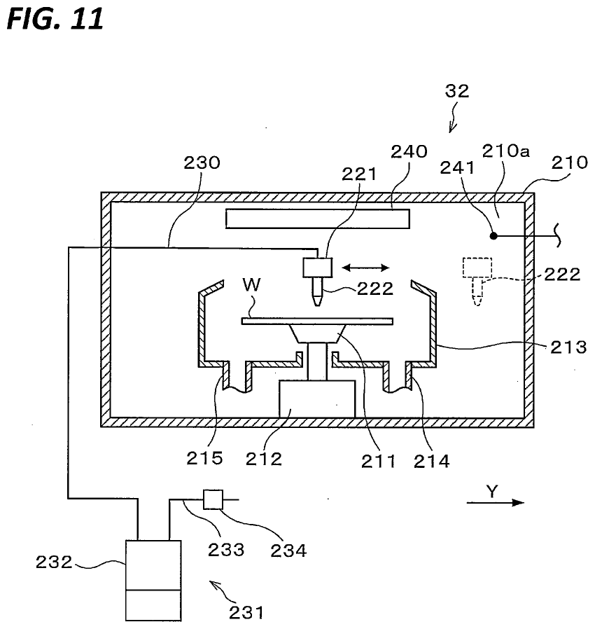

FIG. 11 is a longitudinal cross-sectional view schematically illustrating a configuration of the gas processing unit 32. The gas processing unit 32 includes a processing container 210 as a housing that may be sealed internally as illustrated in FIG. 11, and the processing container 210 has an accommodation space 210a for accommodating a device used in the gas processing of a film formed on the wafer W. A loading/unloading port (not illustrated) for the wafer W is formed on the side of the processing container 210, and an opening/closing shutter (not illustrated) is provided at the loading/unloading port.

A spin chuck 211 is provided centrally within the processing container 210 to hold and rotate the wafer W. The spin chuck 211 has a horizontal upper surface, and a suction port (not illustrated) for sucking the wafer W, for example, is provided on the upper surface. The wafer W may be sucked from the suction port, thus being held on the spin chuck 211 by suction.

The spin chuck 211 is connected to a chuck drive mechanism 212, and may be rotated at a desired speed by the chuck drive mechanism 212. The chuck drive mechanism 212 includes a rotation drive source (not illustrated) such as a motor to generate a drive force for rotating the spin chuck 211. Further, the chuck drive mechanism 212 is provided with a lifting drive source such as a cylinder, allowing the spin chuck 211 to move up and down.

A cup 213 is provided around the spin chuck 211 to receive and collect a liquid scattered or falling from the wafer W. A lower surface of the cup 213 is connected to a discharge pipe 214 for discharging the collected liquid and an exhaust pipe 215 for exhausting the inside of the cup 213.

An arm 221, which is movable in the Y-direction and the vertical direction, is provided above the spin chuck 211. A discharge nozzle 222 is supported on the arm 221. The discharge nozzle 222 discharges dry air containing an acetic acid gas, which is a processing gas containing an acidic gas, toward a portion of the wafer W held on the spin chuck 211.

The discharge nozzle 222 is connected to a supply mechanism 231 through a supply pipe 230. The supply mechanism 231 supplies the dry air containing an acetic acid gas to the discharge nozzle 222. The supply mechanism 231 includes a bottle 232 for storing, for example, acetic acid, a supply pipe 233 for supplying the dry air to the bottle 232, and an opening/closing valve 234 interposed in the supply pipe 233. By supplying the dry air from a dry air source (not illustrated) to the bottle 232 through the supply pipe 233, the dry air containing an acetic acid gas may be supplied to the discharge nozzle 222 through the supply pipe 230. The operation of the supply mechanism 231 is controlled by the controller U.

Furthermore, an FFU 240 is provided above the cup 213 to send clean air downward. The FFU 240 is provided with a filter (not illustrated) to remove acidic gases and is configured to send clean air with removed acidic gases toward the wafer W held on the spin chuck 211.

In the gas processing unit 32 described above, for example, an acidic atmosphere processing is performed on a metal-containing resist film before an exposure processing. In other words, the gas processing unit 32 creates a gas atmosphere different from the atmospheric atmosphere inside the processing container 210. Therefore, it is desirable to use a gas mask as protective gear when performing maintenance work on the gas processing unit 32.

By attaching an RFID tag to the gas mask and pre-registering the gas mask as corresponding protective gear in the controller U (FIG. 1), similar control to the maintenance method for the heat treatment unit 40 described above may be implemented. In other words, when performing maintenance work, an RFID tag of protective gear worn by the operator may be read, and an electronic locking device of a door attached to the processing container 210 may be released only when the protective gear worn by the operator matches corresponding protective gear.

Further, it is desirable to provide a gas concentration sensor 241 in the gas processing unit 32 to measure the processing gas concentration within the processing container 210. Information on the processing gas concentration measured by the gas concentration sensor 241 is output to the controller U illustrated in FIG. 1.

Then, the same control as steps S1 to S7 may be performed by replacing the temperature inside the processing container with the processing gas concentration within the processing container and replacing a predetermined temperature with a predetermined concentration, for example, in step S2 illustrated in FIG. 7. In other words, when protective gear worn by the operator does not match corresponding protective gear, the electronic locking device may be released when the processing gas concentration measured by the gas concentration sensor 241 is below a predetermined concentration. The predetermined concentration referred to here is the processing gas concentration that enables safe breathing for the operator even without wearing a gas mask.

By performing such control, when the processing gas concentration within the processing container 210 has sufficiently decreased during maintenance work, the electronic locking device may be released regardless of whether a gas mask is worn. In other words, when the processing gas concentration within the processing container 210 has sufficiently decreased, the wearing of a gas mask may be omitted, allowing maintenance work to be initiated promptly.

While the development processing unit 30 illustrated in FIG. 2 performs a wet development processing using a developing liquid, the gas processing unit 32 may be configured to perform a dry development processing. Since corrosive gases may be generated during the dry development processing, it is useful to apply the above-described maintenance method using a gas mask with an RFID tag.

### (Delivery Unit)

The fourth block G4 of the processing station 3 illustrated in FIGS. 1 to 3 is provided with the plurality of delivery units 60 to 63 as described above. The inside of housings of these delivery units 60 to 63 is filled with a nitrogen gas, which is an example of an inert gas, creating a nitrogen gas atmosphere.

Therefore, when performing maintenance work on the delivery units 60 to 63, a gas mask (specifically an oxygen mask) is used as protective gear.

By attaching an RFID tag to the gas mask and pre-registering the gas mask as corresponding protective gear in the controller U (FIG. 1), similar control to the maintenance method for the heat treatment unit 40 described above may be implemented. In other words, when performing maintenance work, an RFID tag of protective gear worn by the operator are read, and an electronic locking device of a door attached to the housing may be released only when the protective gear worn by the operator matches corresponding protective gear.

Further, it is desirable to provide a gas concentration sensor (not illustrated) in the delivery units 60 to 63 to measure the inert gas concentration within the housing. Information on the inert gas concentration measured by the gas concentration sensor is output to the controller U illustrated in FIG. 1.

Then, the same control as steps S1 to S7 may be performed by replacing the temperature inside the processing container with the inert gas concentration within the processing container and replacing a predetermined temperature with a predetermined concentration, for example, in step S2 illustrated in FIG. 7. In other words, when protective gear worn by the operator does not match corresponding protective gear, the electronic locking device may be released when the inert gas concentration measured by the gas concentration sensor is below a predetermined concentration. The predetermined concentration referred to here is the inert gas concentration that enables safe breathing for the operator even without wearing a gas mask.

By performing such control, when the inert gas concentration within the housing has sufficiently decreased during maintenance work, the electronic locking device may be released regardless of whether a gas mask is worn. In other words, when the inert gas concentration within the housing has sufficiently decreased, the wearing of a gas mask may be omitted, allowing maintenance work to be initiated promptly.

### (Interface Station)

The inside of a housing of the interface station 5 illustrated in FIGS. 1 to 3 is filled with a nitrogen gas, which is an example of an inert gas, creating a nitrogen gas atmosphere. Therefore, maintenance work may be performed similarly to the above-described delivery units 60 to 63 by using a gas mask (specifically an oxygen mask) as protective gear with an RFID tag.

### (Cleaning System)

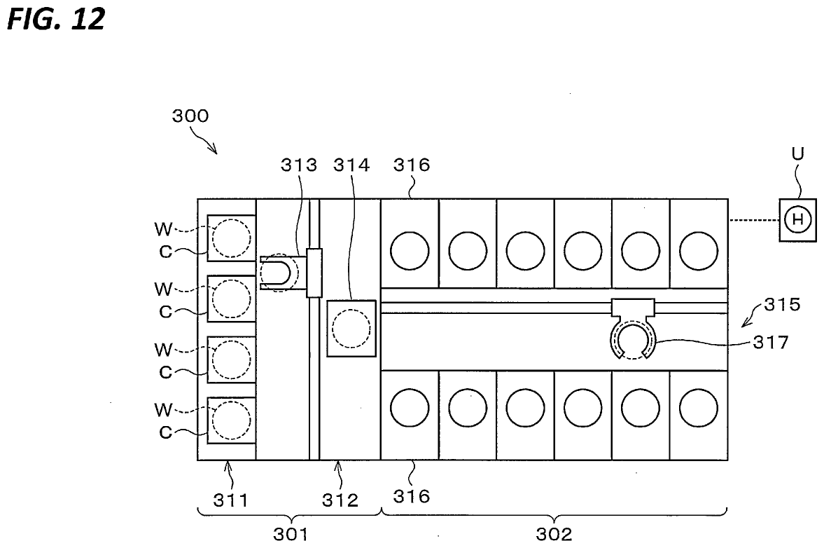

FIG. 12 is an explanatory diagram schematically illustrating an internal configuration of a cleaning system 300 as a substrate processing apparatus. As illustrated in FIG. 12, the cleaning system 300 includes a loading/unloading station 301 and a processing station 302. The loading/unloading station 301 and the processing station 302 are provided adjacent to each other.

The loading/unloading station 301 includes a cassette placement section 311 and a transfer section 312. In the cassette placement section 311, a plurality of cassettes C are arranged to horizontally accommodate multiple wafers W as substrates.

The transfer section 312 is provided adjacent to the carrier placement section 311 and contains a transfer device 313 and a deliverer 314 therein. The transfer device 313 has a wafer holding mechanism for holding the wafers W. Further, the transfer device 313 is capable of moving in both the horizontal and vertical directions as well as pivoting around a vertical axis. It transfers the wafers W between the cassettes C and the deliverer 314 using the wafer holding mechanism.

The processing station 302 is provided adjacent to the transfer section 312. The processing station 302 includes a transfer section 315 and a plurality of cleaning units 316. The plurality of cleaning units 316 are arranged on both sides of the transfer section 315.

The transfer section 315 contains a transfer device 317 therein. The transfer device 317 has a wafer holding mechanism for holding the wafers W. Further, the transfer device 317 is capable of moving in both the horizontal and vertical directions as well as pivoting around a vertical axis. It transfers the wafers W between the deliverer 314 and the cleaning units 316 using the wafer holding mechanism.

The cleaning units 316 as cleaning devices perform a cleaning processing on the wafers W transferred by the transfer device 317.

Further, the cleaning system 300 includes the controller U. The controller U is a computer equipped with, for example, a processor such as CPU, a memory, etc., and has a program storage (not illustrated). The program storage stores programs that control the operations of the various transfer devices and the cleaning units 316 described above. Here, the above programs were recorded on a computer-readable storage medium H, and may be installed from the storage medium H to the controller U. The storage medium M may be either transitory or non-transitory. Some or all of the programs may be realized with dedicated hardware (circuit board).

In the cleaning system 300 configured as described above, first, the transfer device 313 of the loading/unloading station 301 retrieves the wafers W from the cassettes C placed in the cassette placement section 311 and places the retrieved wafers W onto the deliverer 314. The wafers W placed on the deliverer 314 are then retrieved from the deliverer 314 by the transfer device 317 of the processing station 302, and are loaded into the cleaning units 316.

After the wafers W loaded into the cleaning units 316 are cleaned by the cleaning units 316, the wafers W are unloaded from the cleaning units 316 by the transfer device 317 and are placed onto the deliverer 314. Then, the processed wafers W placed on the deliverer 314 are returned to the cassettes C of the cassette placement section 311 by the transfer device 313.

### (Cleaning Unit)

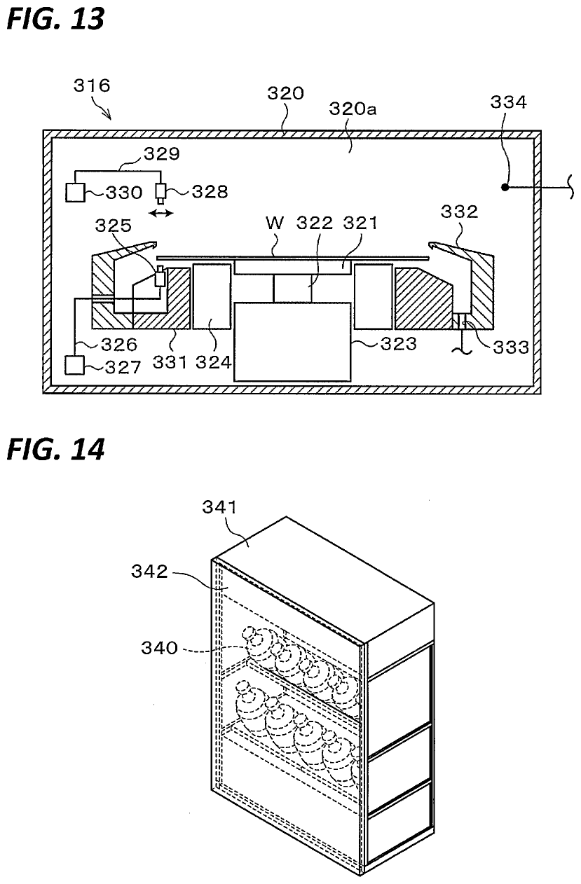

FIG. 13 is a longitudinal cross-sectional view schematically illustrating a configuration of the cleaning unit 316. The cleaning unit 316 includes a processing container 320 as a housing, and the processing container 320 has an accommodation space 320a that accommodates a device used for cleaning the wafer W.

A spin chuck 321 is provided within the processing container 320 to rotatably hold the wafer W. The spin chuck 321 holds the wafer W by vacuum suction. The spin chuck 321 has a smaller diameter than the wafer W and holds the center of a lower surface of the wafer W by suction. A shaft 322 horizontally supports the spin chuck 321 at a tip end thereof. A drive 323 is connected to a base end of the shaft 322 to rotate the shaft 322 around a vertical axis.

A heating mechanism 324 is provided below the wafer W and outward from the spin chuck 321. The heating mechanism 324 heats the peripheral edge of the lower surface of the wafer W held by the spin chuck 321 by supplying a heated fluid to the lower surface of the wafer W. Specifically, the heating mechanism 324 has a plurality of discharge ports (not illustrated) arranged in the circumferential direction of the wafer W, and supplies the heated fluid to the lower surface of the wafer W from these discharge ports.

A lower surface nozzle 325 is provided within the processing container 320 to supply a cleaning liquid as a processing liquid to the peripheral edge of the lower surface of the wafer W. The lower surface nozzle 325 is positioned below the wafer W and discharges the cleaning liquid upward toward the peripheral edge of the lower surface of the wafer W. A pipe 326 connects the lower surface nozzle 325 to a cleaning liquid source 327. The cleaning liquid source 327 is, for example, a tank storing the cleaning liquid.

The supply of the cleaning liquid from the lower surface nozzle 325 to the peripheral edge of the lower surface of the wafer W enables the removal of a film formed on the peripheral edge of the lower surface of the wafer W, or the cleaning of the peripheral edge of the lower surface of the wafer W.

An upper surface nozzle 328 is provided above the wafer W to discharge the cleaning liquid onto an upper surface of the wafer W. The upper surface nozzle 328 is oriented such that a discharge port thereof faces downward. Further, the upper surface nozzle 328 is configured to be movable in the horizontal direction, which enables the movement of the upper surface nozzle 328 between a processing position above the wafer W and a retracted position outward from the wafer W. A pipe 329 connects the upper surface nozzle 328 to a cleaning liquid source 330. The cleaning liquid source 330 is, for example, a tank storing the cleaning liquid.

Examples of the cleaning liquid may include hydrofluoric acid (HF), dilute hydrofluoric acid (DHF), nitric hydrofluoric acid, deionized water (DIW), etc. Nitric hydrofluoric acid is a mixture of hydrofluoric acid (HF) and nitric acid (HNO₃).

A circular lower cup 331 is provided below the wafer W and outward from the heating mechanism 324. The lower cup 331 is made of a highly chemically resistant material, for example, fluorine resin such as polytetrafluoroethylene (PTFE) or perfluoroalkoxyalkane (PFA).

An outer cup 332 is an annular member formed to surround the wafer W, and collects the cleaning liquid and others scattered from the wafer W. A drain port 333 is formed at the bottom of the outer cup 332. The cleaning liquid and others collected by the outer cup 332 are stored in the space formed by the outer cup 332 and the lower cup 331, and are then discharged to the outside of the cleaning unit 316 through the drain port 333.

Given that the cleaning liquid is used in the cleaning unit 316 described above, protective gear during maintenance may be, for example, cleaning-liquid protective goggles to protect the operator's eyes from splashing cleaning liquid. Further, since the cleaning unit 316 is provided with the heating mechanism 324, heat-resistant gloves are used as protective gear during maintenance work.

By attaching RFID tags to the protective gear and pre-registering the protective gear as corresponding protective gear in the controller U (FIG. 12), similar control to the maintenance method for the heat treatment unit 40 described above may be implemented. In other words, when performing maintenance work, an RFID tag of protective gear worn by the operator may be read, and an electronic locking device of a door attached to the processing container 320 may be released only when the protective gear worn by the operator matches corresponding protective gear.

However, in the cleaning unit 316, the concentration of the cleaning liquid contained in the atmosphere within the processing container 320 increases due to the volatilization of the cleaning liquid. Therefore, it is desirable to register a gas mask as corresponding protective gear from the viewpoint of further enhancing the safety of operators performing maintenance work.

Further, it is desirable to provide a gas concentration sensor 334 in the cleaning unit 316 to measure the concentration of the volatilized cleaning liquid contained in the atmosphere within the processing container 320. Information on the gas concentration measured by the gas concentration sensor 334 is output to the controller U illustrated in FIG. 12.

Then, the same control as steps S1 to S7 may be performed by replacing the temperature inside the processing container with the concentration of the volatilized cleaning liquid contained in the atmosphere within the processing container and replacing a predetermined temperature with a predetermined concentration, for example, in step S2 illustrated in FIG. 7. In other words, when protective gear worn by the operator does not match corresponding protective gear, the electronic locking device may be released when the concentration of the volatilized cleaning liquid contained in the atmosphere within the processing container measured by the gas concentration sensor 334 is below a predetermined concentration. The predetermined concentration referred to here is the concentration that enables safe breathing for the operator even without wearing a gas mask.

By performing such control, when the concentration of the volatilized cleaning liquid within the processing container 320 has sufficiently decreased during maintenance work, the electronic locking device may be released regardless of whether a gas mask is worn. In other words, when the volatilized cleaning liquid atmosphere concentration within the processing container 320 has sufficiently decreased, the wearing of a gas mask may be omitted, allowing maintenance work to be initiated promptly.

The volatilization of the processing liquid is not limited to the cleaning liquid, but may also occur, for example, in the resist liquid used in the resist coating unit 31 or the developing liquid used in the development processing unit 30 as described above. Therefore, it is desirable to register a gas mask as corresponding protective gear in the resist coating unit 31 and the development processing unit 30 as well.

### (Liquid Reservoir)

FIG. 14 is an explanatory diagram illustrating an accommodation container of a liquid reservoir for storing various processing liquids. In order to supply various processing liquids to liquid processing units such as the above-described resist coating unit 31, development processing unit 30, and cleaning unit 316, a bottle 340 as a liquid reservoir is placed near each liquid processing unit.

The bottle 340 is accommodated within a container 341, which is an example of a housing. The container 341 further accommodates devices used for the liquid processing of the wafer W such as piping and pumps (not illustrated). Further, a door 342 with an electronic locking device is attached to the container 341.

When performing maintenance work on the liquid reservoir of the processing liquid described above, protective gear to be used may be, for example, processing-liquid protective goggles to protect the operator's eyes from splashing processing liquid, and chemical-resistant gloves or chemical-resistant aprons made of chemical-resistant materials.

Then, by attaching RFID tags to the protective gear and pre-registering the protective gear as corresponding protective gear in the controller, similar control to the maintenance method for the heat treatment unit 40 described above may be implemented. In other words, when performing maintenance work, an RFID tag of protective gear worn by the operator may be read, and the electronic locking device attached to the door 342 may be released only when the protective gear worn by the operator matches corresponding protective gear.

### (Electrical Component Accommodating Section)

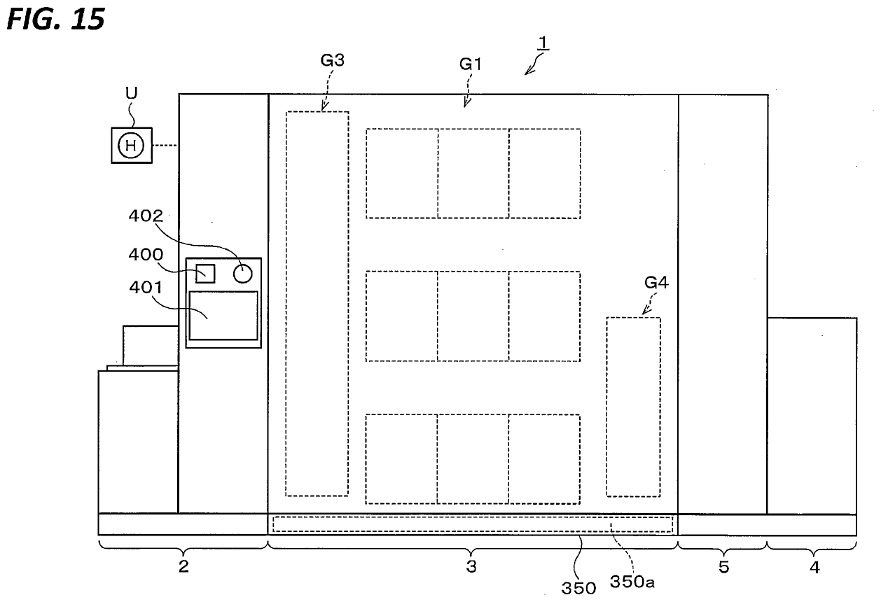

FIG. 15 is a diagram of the front side of the coating/development processing apparatus 1 as seen from the outside of the apparatus. Electrical components required for the operation of various wafer processing units are arranged, for example, under the floor of the processing station 3 of the coating/development processing apparatus 1. Specifically, a container 350 as a housing is arranged under the floor of the coating/development processing apparatus 1, and electrical components are accommodated in an accommodating space 350a formed within the container 350.

By attaching a door with an electronic locking device to the container 350 and registering insulating gloves made of an insulating material as corresponding protective gear in the controller U, similar control to the maintenance method of the heat treatment unit 40 described above may be performed. In other words, when performing maintenance work, an RFID tag of protective gear worn by the operator may be read, and the electronic locking device of the door may be released only when the protective gear worn by the operator matches corresponding protective gear.

In the example illustrated in FIG. 15, it is permissible for the electrical component accommodating section to be arranged under the floor of the processing station 3 and adjacent to the side of the processing station 3.

As described above, the maintenance method using protective gear with an RFID tag may be applied to various maintenance targets. Further, while there are a variety of housings that accommodate devices used for wafer processing, an example of whether corresponding protective gear is required for each housing type is summarized in Table I below.

TABLE 1

| | | Type of housing | | | | | | | |
|---|---|---|---|---|---|---|---|---|---|
| | | | Liquid processing | | | | Inert gas | | Electrical |
| | | | Coating | | Light irradiation | | atmosphere/ | | component |
| | | Heat | liquid/ | | Laser | UV | Gas | Liquid | accommodating |
| | | treatment | development | Cleaning | irradiation | irradiation | processing | reservoir | section |
| Corresponding | Heat- | Required | — | Required | Required | — | — | — | — |
| Protective | resist | | | | | | | | |
| Gear | gloves | | | | | | | | |
| | Liquid | — | Required | Required | — | — | — | Required | — |
| | protective | | | | | | | | |
| | goggles | | | | | | | | |
| | Chemical- | — | Required | — | — | — | — | Required | — |
| | resistant | | | | | | | | |
| | gloves | | | | | | | | |
| | Chemical- | — | Required | — | — | — | — | Required | — |
| | resistant | | | | | | | | |
| | aprons | | | | | | | | |
| | Light | — | — | — | Required | Required | — | — | — |
| | protective | | | | | | | | |
| | goggles | | | | | | | | |
| | Gas mask | — | — | — | — | Required | Required | — | — |
| | Insulating | — | — | — | — | — | — | — | Required |
| | gloves | | | | | | | | |

### Preferred Control Examples

In a substrate processing apparatus capable of performing maintenance work using protective gear with an RFID tag, it is desirable to combine the following control examples.

The coating/development processing apparatus 1 illustrated in FIG. 15 is provided with a non-contact-type IC card reader 400 as an identifier for reading and identifying maintenance operator's specific information. The IC card reader 400 reads an IC card such as employee ID card owned by the operator. Further, specific information for each operator such as ID number is pre-registered in the controller U.

In this coating/development processing apparatus 1, it is desirable to perform control that releases an electronic locking device of a maintenance target when protective gear worn by the operator matches corresponding protective gear and when the ID number read by the IC card reader 400 matches pre-registered ID number.

By performing such control, the electronic locking device may be released only when the operator attempting maintenance work is a predetermined operator. This ensures that only designated maintenance personnel are allowed to perform maintenance work, for example, when different maintenance personnel are assigned to each of multiple coating/development processing apparatuses.

In addition, the IC card reader 400 is used as the identifier in the above example, but biometric authentication such as fingerprint authentication may also be used to identify the operator. In other words, the identifier may have any configuration capable of identifying the operator. Further, the function of the identifier may be included in the afore-mentioned detector.

The coating/development processing apparatus 1 illustrated in FIG. 15 is provided with a touch panel 401 as a display. The touch panel 401 also functions as an input unit for operating the coating/development processing apparatus 1.

In this coating/development processing apparatus 1, it is desirable to perform control that enables the display of a dedicated operation screen on the touch panel 401 when the ID number of the IC card read by the IC card reader 400 matches pre-registered ID number.

By performing such control, the touch panel 410 may display a dedicated operation screen for that operator only when the operator attempting maintenance work was a predetermined operator. This ensures that only designated maintenance personnel are allowed to perform maintenance work, for example, when different maintenance personnel are assigned to each of multiple coating/development processing apparatuses, or when different maintenance personnel are assigned to each processing unit within a single coating/development processing apparatus.

The coating/development processing apparatus 1 illustrated in FIG. 15 is provided with an LED lamp 402 as an emitter. The LED lamp 402 lights up based on a signal input from the controller U.

In this coating/development processing apparatus 1, it is desirable to perform control that lights up the LED lamp 402 when the ID number of the IC card read by the IC card reader 400 matches pre-registered ID number.

By performing such control, the LED lamp 402 lights up only when the operator attempting maintenance work was a predetermined operator. In other words, since the LED lamp 402 will not light up when an operator other than designated maintenance personnel attempts maintenance work, it is possible to notify the operator operating the touch panel 401 that the operator is operating a device outside his/her assigned responsibility.

The substrate processing apparatus and the maintenance method thereof according to the embodiment have been described above.

In addition, an RFID reader was used as a detector for detecting protective gear worn by the operator in the above explanation, but the detector for detecting protective gear worn by the operator is not limited to a system using RFID. For example, an imaging device such as a camera may be used as the detector to detect the protective gear worn by the operator.

Further, the effects described in this specification are merely explanatory or illustrative and not limiting. In other words, the technology of the present disclosure may achieve effects that are clear to those skilled in the art from the description of this specification, in addition to or instead of the above effects.

In addition, the following configuration examples also belong to the technical scope of the present disclosure.

(1) A substrate processing apparatus that processes a substrate, the apparatus including:
a housing having an accommodation space that accommodates a device used to process the substrate;
a switch that switches the accommodation space between an open state and a closed state;
a detector that is provided around the housing and detects a protective gear worn by an operator; and
a controller that controls an operation of the switch,
wherein the controller
determines whether the worn protective gear detected by the detector is pre-registered protective gear corresponding to the housing, and
when determined that the worn protective gear is the corresponding protective gear, switches the accommodation space from the closed state to the open state.

(2) The substrate processing apparatus according to (1), in which the housing is a processing container of a heat treatment apparatus that heats the substrate, and the corresponding protective gear includes heat-resistant gloves.

(3) The substrate processing apparatus according to (2), further including a temperature sensor that measures a temperature inside the processing container, and
in which the controller:
when determined that the worn protective gear is the corresponding protective gear, switches the accommodation space from the closed state to the open state; and
when determined that the worn protective gear is not the corresponding protective gear, switches the accommodation space from the closed state to the open state when the temperature measured by the temperature sensor is below a predetermined temperature.

(4) The substrate processing apparatus according to (1), in which the housing is a processing container of a liquid processing apparatus that supplies a processing liquid to the substrate to perform a liquid processing, and
the corresponding protective gear includes liquid protective goggles that protect the operator from the processing liquid.

(5) The substrate processing apparatus according to (4), further including a gas concentration sensor that measures a concentration of the processing liquid volatilized in an atmosphere within the processing container,
in which the corresponding protective gear includes a gas mask, and
the controller:
when determined that the worn protective gear is the corresponding protective gear, switches the accommodation space from the closed state to the open state; and
when determined that the worn protective gear is not the corresponding protective gear, switches the accommodation space from the closed state to the open state when the concentration of the processing liquid volatilized in the atmosphere within the processing container measured by the gas concentration sensor is below a predetermined concentration.

(6) The substrate processing apparatus according to (1), in which the housing is a processing container of a light irradiation apparatus that irradiates the substrate with light, and
the corresponding protective gear includes light protective goggles that protect eyes of the operator against the light.

(7) The substrate processing apparatus according to (1), in which the housing is a housing filled with a gas different from an atmospheric atmosphere within the accommodation space, and
the corresponding protective gear is a gas mask.

(8) The substrate processing apparatus according to (7), further including a gas concentration sensor that measures a concentration of the gas within the housing, and
in which the controller:
when determined that the worn protective gear is the corresponding protective gear, switches the accommodation space from the closed state to the open state, and
when determined that the worn protective gear is not the corresponding protective gear, switches the accommodation space from the closed state to the open state when the concentration of the gas measured by the gas concentration sensor is below a predetermined concentration.

(9) The substrate processing apparatus according to (1), in which the housing is a container where a reservoir is placed to store a processing liquid supplied to the substrate, and
the corresponding protective gear includes liquid protective goggles that protect eyes of the operator from the processing liquid.

(10) The substrate processing apparatus according to (1), in which the housing is a container that accommodates an electrical component, and
the corresponding protective gear includes insulating gloves.

(11) The substrate processing apparatus according to any one of (1) to (10), further including an identifier that identifies specific information of the operator who operates the substrate processing apparatus,
in which the controller switches the accommodation space from the closed state to the open state when determined that the worn protective gear is the corresponding protective gear and when the operator identified by the identifier is a predetermined operator.

(12) The substrate processing apparatus according to any one of (1) to (11), further including:
an identifier that identifies specific information of the operator who operates the substrate processing apparatus; and
a display that displays an operation screen of the substrate processing apparatus,
in which the controller displays the operation screen dedicated to a predetermined operator on the display when the operator identified by the identifier is the predetermined operator.

(13) The substrate processing apparatus according to any one of (1) to (12), further including:
an identifier that identifies specific information of the operator who operates the substrate processing apparatus; and
an emitter that lights up based on a signal input from the controller,
in which the controller light ups the emitter when the operator identified by the identifier is a predetermined operator.

According to the present disclosure, it is possible to enhance the safety of operators during maintenance work on a substrate processing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a housing having an accommodation space that accommodates an apparatus used to process the substrate;
a switch configured to switch the accommodation space between an open state and a closed state;
a detector provided around the housing and configured to detect a protective gear worn by an operator; and
a controller configured to control an operation of the switch,
wherein the controller
determines whether the worn protective gear detected by the detector is a pre-registered protective gear corresponding to the housing, and
when determined that the worn protective gear is the corresponding protective gear, switches the accommodation space from the closed state to the open state.

2. The substrate processing apparatus according to claim 1, wherein the housing is a processing container of a heat treatment apparatus that heats the substrate, and
the corresponding protective gear includes a heat-resistant glove.

3. The substrate processing apparatus according to claim 2, further comprising a temperature sensor that measures a temperature inside the processing container, and
wherein the controller:
when determined that the worn protective gear is the corresponding protective gear, switches the accommodation space from the closed state to the open state; and
when determined that the worn protective gear is not the corresponding protective gear, switches the accommodation space from the closed state to the open state when the temperature measured by the temperature sensor is below a predetermined temperature.

4. The substrate processing apparatus according to claim 1, wherein the housing is a processing container of a liquid processing apparatus that supplies a processing liquid to the substrate to perform a liquid processing, and
the corresponding protective gear includes liquid protective goggles that protects the operator from the processing liquid.

5. The substrate processing apparatus according to claim 4, further comprising a gas concentration sensor that measures a concentration of the processing liquid volatilized in an atmosphere within the processing container,
wherein the corresponding protective gear includes a gas mask, and
the controller,
when determined that the worn protective gear is the corresponding protective gear, switches the accommodation space from the closed state to the open state, and
when determined that the worn protective gear is not the corresponding protective gear, switches the accommodation space from the closed state to the open state when the concentration of the processing liquid volatilized in the atmosphere within the processing container measured by the gas concentration sensor is below a predetermined concentration.

6. The substrate processing apparatus according to claim 1, wherein the housing is a processing container of a light irradiation apparatus that irradiates the substrate with light, and
the corresponding protective gear includes light protective goggles that protects eyes of the operator against the light.

7. The substrate processing apparatus according to claim 1, wherein the housing is a housing filled with a gas different from an atmospheric atmosphere within the accommodation space, and
the corresponding protective gear is a gas mask.

8. The substrate processing apparatus according to claim 7, further comprising a gas concentration sensor that measures a concentration of the gas within the housing, and
wherein the controller:
when determined that the worn protective gear is the corresponding protective gear, switches the accommodation space from the closed state to the open state, and
when determined that the worn protective gear is not the corresponding protective gear, switches the accommodation space from the closed state to the open state when the concentration of the gas measured by the gas concentration sensor is below a predetermined concentration.

9. The substrate processing apparatus according to claim 1, wherein the housing is a container where a reservoir is placed to store a processing liquid supplied to the substrate, and
the corresponding protective gear includes liquid protective goggles that protects eyes of the operator from the processing liquid.

10. The substrate processing apparatus according to claim 1, wherein the housing is a container that accommodates an electrical component, and
the corresponding protective gear includes insulating gloves.

11. The substrate processing apparatus according to claim 1, further comprising an identifier that identifies specific information of the operator who operates the substrate processing apparatus,
wherein the controller switches the accommodation space from the closed state to the open state when determined that the worn protective gear is the corresponding protective gear and when the operator identified by the identifier is a predetermined operator.

12. The substrate processing apparatus according to claim 1, further comprising:
an identifier configured to identify specific information of the operator who operates the substrate processing apparatus; and
a display configured to display an operation screen of the substrate processing apparatus,
wherein the controller displays the operation screen dedicated to a predetermined operator on the display when the operator identified by the identifier is the predetermined operator.

13. The substrate processing apparatus according to claim 1, further comprising:
an identifier configured to identify specific information of the operator who operates the substrate processing apparatus; and
an emitter configured to light up based on a signal input from the controller,
wherein the controller lights up the emitter when the operator identified by the identifier is a predetermined operator.

14. A maintenance method for a substrate processing apparatus, the maintenance method comprising:
during maintenance work, switching an accommodation space of a housing that accommodates an apparatus used to process a substrate from a closed state to an open state when determined that a protective gear worn by an operator detected by a detector provided around the housing to detect the protective gear is a pre-registered protective gear corresponding to the housing.

15. The maintenance method according to claim 14, wherein the housing is a processing container of a heat treatment apparatus that heats the substrate, and
the corresponding protective gear includes a heat-resistant glove.

16. The maintenance method according to claim 15, further comprising:
during the maintenance work, when determined that the worn protective gear is not the corresponding protective gear, switching the accommodation space from the closed state to the open state when the temperature measured by the temperature sensor is below a predetermined temperature.

17. The maintenance method according to claim 14, wherein the housing is a processing container of a liquid processing apparatus that supplies a processing liquid to the substrate to perform a liquid processing, and
the corresponding protective gear includes liquid protective goggles that protects eyes of the operator from the processing liquid.

18. The maintenance method according to claim 17, wherein the corresponding protective gear includes a gas mask, and
the maintenance method further comprises:
during the maintenance work, when determined that the worn protective gear is not the corresponding protective gear, switching the accommodation space from the closed state to the open state when a concentration of the processing liquid volatilized in an atmosphere within the processing container is below a predetermined concentration.

19. The maintenance method according to claim 14, wherein the housing is a processing container of a light irradiation apparatus that irradiates the substrate with light, and
the corresponding protective gear includes light protective goggles that protect eyes of the operator against the light.

20. A non-transitory computer-readable storage medium having stored therein a program that causes a computer to execute a maintenance method for a substrate processing apparatus, the maintenance method comprising:
during maintenance work, switching an accommodation space of a housing that accommodates an apparatus used to process a substrate from a closed state to an open state when determined that a protective gear worn by an operator detected by a detector provided around the housing to detect the protective gear is a pre-registered protective gear corresponding to the housing.
